(19) United States
(12) Patent Application Publication
(10) Pub. No.: US 2026/0190213 A1
(43) Pub. Date: Jul. 2, 2026

(54) HYBRID PRINTED CIRCUIT BOARD AND BATTERY PACK INCLUDING THE SAME

(71) Applicant: SAMSUNG SDI CO., LTD., Yongin-si (KR)

(72) Inventors: Young Hyun LEE, Suwon-si (KR); Bong Koun JANG, Suwon-si (KR)

(21) Appl. No.: 19/418,045

(22) Filed: Dec. 12, 2025

(30) Foreign Application Priority Data
Dec. 31, 2024 (KR) 10-2024-0202198

(51) Int. Cl. H05K 1/02; H01M 50/284; H05K 1/14

(52) U.S. Cl. CPC H05K 1/0209; H01M 50/284; H05K 1/028; H05K 1/142

(57) ABSTRACT

A hybrid printed circuit board and a battery pack including the same are disclosed. A hybrid printed circuit board includes: a flexible printed circuit board including a flexible film that is bendable, and a flexible conductive layer stacked on the flexible film, the flexible printed circuit board including a bending part located on a first side and a heat dissipation promoting part located on a second side; and a heat dissipation printed circuit board overlapping the heat dissipation promoting part and electrically connected to the flexible conductive layer.

### CROSS-REFERENCE TO RELATED APPLICATION

The present application claims priority to and the benefit of Korean Patent Application No. 10-2024-0202198, filed on Dec. 31, 2024 in the Korean Intellectual Property Office, the entire disclosure of which is incorporated herein by reference.

### BACKGROUND

### 1. Field

Aspects of embodiments of the present disclosure relate to a hybrid printed circuit board and a battery pack including the same.

### 2. Description of Related Art

Generally, a small battery pack including a pouch type secondary battery is used as an energy source in portable electronic devices, such as a laptop computer, a video camera, or a mobile phone.

The small battery pack may include a flexible printed circuit board (FPCB) that electrically connects a main body of an electronic device and a secondary battery.

The aforementioned information disclosed in this background section is provided to facilitate understanding of the background technology of the present disclosure and may contain information that does not constitute the related art.

### SUMMARY

According to an aspect of embodiments of the present disclosure, a hybrid printed circuit board in which an allowable current is increased and heat generation is reduced without degrading bending performance, and a battery pack including the same, are provided.

However, aspects and technical objectives to be achieved by the present disclosure are not limited to the above-described aspects and objectives, and other aspects and objectives, which are not described above, will be clearly understood by those skilled in the art through the following description of the disclosure.

According to one or more embodiments of the present disclosure, a hybrid printed circuit board includes: a flexible printed circuit board including a flexible film that is bendable and a flexible conductive layer stacked on the flexible film, the flexible printed circuit board including a bending part located on a first side and a heat dissipation promoting part located on a second side; and a heat dissipation printed circuit board overlapping the heat dissipation promoting part and electrically connected to the flexible conductive layer.

The flexible printed circuit board may include a heat dissipation printed circuit board connection terminal connected to the flexible conductive layer on the heat dissipation promoting part, and the heat dissipation printed circuit board may include a base, a heat dissipation conductive layer stacked on the base, and a flexible printed circuit board connection terminal connected to the heat dissipation conductive layer and electrically connected to the heat dissipation printed circuit board connection terminal.

The hybrid printed circuit board may further include a solder layer joining the heat dissipation printed circuit board connection terminal and the flexible printed circuit board connection terminal.

The flexible printed circuit board connection terminal may be on a first side surface of the base facing the heat dissipation printed circuit board connection terminal, the heat dissipation conductive layer may be on a second side surface of the base facing away from the first side surface, and the heat dissipation printed circuit board may further include a via hole passing through the base in a thickness direction to connect the flexible printed circuit board connection terminal and the heat dissipation conductive layer.

The flexible conductive layer may include a first flexible conductive layer and a second flexible conductive layer spaced apart from the first flexible conductive layer, and the heat dissipation printed circuit board connection terminal may include a first heat dissipation printed circuit board connection terminal connected to the first flexible conductive layer and a second heat dissipation printed circuit board connection terminal connected to the second flexible conductive layer.

The heat dissipation printed circuit board may include a first heat dissipation printed circuit board and a second heat dissipation printed circuit board spaced apart from each other.

The first heat dissipation printed circuit board may include a first base, a first heat dissipation conductive layer stacked on the first base, and a first flexible printed circuit board connection terminal connected to the first heat dissipation conductive layer and electrically connected to the first heat dissipation printed circuit board connection terminal.

The second heat dissipation printed circuit board may include a second base, a second heat dissipation conductive layer stacked on the second base, and a second flexible printed circuit board connection terminal connected to the second heat dissipation conductive layer and electrically connected to the second heat dissipation printed circuit board connection terminal.

The heat dissipation conductive layer may include a first heat dissipation conductive layer and a second heat dissipation conductive layer on the base and spaced apart from each other, and the flexible printed circuit board connection terminal may include a first flexible printed circuit board connection terminal on the base and connected to the first heat dissipation conductive layer and a second flexible printed circuit board connection terminal on the base and connected to the second heat dissipation conductive layer.

A thickness of the heat dissipation printed circuit board may be greater than a thickness of the flexible printed circuit board.

A width of the heat dissipation promoting part may be greater than a width of the bending part.

The flexible conductive layer may include a bending part flexible conductive layer on the bending part and a heat dissipation promoting part flexible conductive layer on the heat dissipation promoting part, and a width of the heat dissipation promoting part flexible conductive layer may be greater than a width of the bending part flexible conductive layer.

The bending part may include a bending line that divides a first side and a second side of the bending part and extends along a straight line, and the bending part may be folded along the bending line such that the first side and the second side of the bending part overlap.

According to one or more embodiments of the present disclosure, a battery pack includes: a secondary battery; and a hybrid printed circuit board including: a flexible printed circuit board that includes a flexible film that is bendable and a flexible conductive layer stacked on the flexible film, the flexible printed circuit board including a bending part located on a first side and a heat dissipation promoting part located on a second side; and a heat dissipation printed circuit board overlapping the heat dissipation promoting part and electrically connected to the flexible conductive layer.

The battery pack may further include a battery pack printed circuit board connected to a terminal of the secondary battery, wherein the flexible printed circuit board may further include a board connection terminal connected to the battery pack printed circuit board at the bending part, and a connector arranged at the heat dissipation promoting part.

The flexible printed circuit board may include a heat dissipation printed circuit board connection terminal connected to the flexible conductive layer on the heat dissipation promoting part, and the heat dissipation printed circuit board may include a base, a heat dissipation conductive layer stacked on the base, and a flexible printed circuit board connection terminal connected to the heat dissipation conductive layer and electrically connected to the heat dissipation printed circuit board connection terminal.

The flexible conductive layer may include a first flexible conductive layer and a second flexible conductive layer spaced apart from the first flexible conductive layer, and the heat dissipation printed circuit board connection terminal may include a first heat dissipation printed circuit board connection terminal connected to the first flexible conductive layer and a second heat dissipation printed circuit board connection terminal connected to the second flexible conductive layer.

The heat dissipation printed circuit board may include a first heat dissipation printed circuit board and a second heat dissipation printed circuit board spaced apart from each other.

The first heat dissipation printed circuit board may include a first base, a first heat dissipation conductive layer stacked on the first base, and a first flexible printed circuit board connection terminal connected to the first heat dissipation conductive layer and electrically connected to the first heat dissipation printed circuit board connection terminal, and the second heat dissipation printed circuit board may include a second base, a second heat dissipation conductive layer stacked on the second base, and a second flexible printed circuit board connection terminal connected to the second heat dissipation conductive layer and electrically connected to the second heat dissipation printed circuit board connection terminal.

The heat dissipation conductive layer may include a first heat dissipation conductive layer and a second heat dissipation conductive layer on the base and spaced apart from each other, and the flexible printed circuit board connection terminal may include a first flexible printed circuit board connection terminal on the base and connected to the first heat dissipation conductive layer and a second flexible printed circuit board connection terminal on the base and connected to the second heat dissipation conductive layer.

### BRIEF DESCRIPTION OF THE DRAWINGS

The above and other objects, features and advantages of the present disclosure will become more apparent to those of ordinary skill in the art by describing some embodiments thereof in further detail with reference to the accompanying drawings, in which:

FIG. 1 is a plan view of a battery pack according to an embodiment of the present invention illustrating a state in which a flexible printed circuit board is not folded;

FIG. 2 is a plan view of a battery pack according to an embodiment of the present invention illustrating a state in which a flexible printed circuit board is folded;

FIG. 3 is a plan view illustrating a hybrid printed circuit board according to an embodiment of the present invention;

FIG. 4 is a plan view of a flexible printed circuit board of FIG. 3;

FIG. 5 is a plan view of a heat dissipation printed circuit board of FIG. 3;

FIG. 6 is a cross-sectional view taken along the line S1-S1 of FIG. 3;

FIG. 7 is a cross-sectional view taken along the line S2-S2 of FIG. 3;

FIG. 8 is a plan view illustrating a hybrid printed circuit board according to another embodiment of the present invention; and

FIG. 9 is a cross-sectional view taken along the line S3-S3 of FIG. 8.

### DETAILED DESCRIPTION

Herein, some embodiments of the present disclosure will be described in further detail with reference to the accompanying drawings. The terms or words used in this specification and claims are not to be construed as being limited to the usual or dictionary meaning and are to be interpreted as having meaning and concept consistent with the technical idea of the present disclosure based on the principle that the inventor can be his/her own lexicographer to appropriately define the concept of the term.

The embodiments described in this specification and the configurations shown in the drawings are provided as some example embodiments of the present disclosure and do not necessarily represent all of the technical ideas, aspects, and features of the present disclosure. Accordingly, it is to be understood that there may be various equivalents and modifications that may replace or modify the embodiments described herein at the time of filing this application.

It is to be understood that when an element or layer is referred to as being “on,” “connected to,” or “coupled to” another element or layer, it may be directly on, connected, or coupled to the other element or layer, or one or more intervening elements or layers may also be present. When an element or layer is referred to as being “directly on,” “directly connected to,” or “directly coupled to” another element or layer, there are no intervening elements or layers present. For example, when a first element is described as being “coupled” or “connected” to a second element, the first element may be directly coupled or connected to the second element, or the first element may be indirectly coupled or connected to the second element via one or more intervening elements.

In the figures, dimensions of the various elements, layers, etc. may be exaggerated for clarity of illustration. The same reference numerals designate the same or like elements. As used herein, the term “and/or” includes any and all combinations of one or more of the associated listed items. Further, the use of “may” when describing embodiments of the present disclosure relates to “one or more embodiments of the present disclosure.” Expressions, such as “at least one of” and “any one of,” when preceding a list of elements, modify the entire list of elements and do not modify the individual elements of the list. When phrases such as “at least one of A, B, and C,” “at least one of A, B, or C,” “at least one selected from a group of A, B, and C,” or “at least one selected from among A, B, and C” are used to designate a list of elements A, B, and C, the phrase may refer to any and all suitable combinations or a subset of A, B, and C, such as A, B, C, A and B, A and C, B and C, or A and B and C. As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

It is to be understood that, although the terms “first,” “second,” “third,” etc. may be used herein to describe various elements, components, regions, layers, and/or sections, these elements, components, regions, layers, and/or sections are not to be limited by these terms. These terms are used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It is to be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (e.g., rotated 90 degrees or at other orientations), and the spatially relative descriptors used herein are to be interpreted accordingly.

The terminology used herein is for the purpose of describing embodiments of the present disclosure and is not intended to be limiting of the present disclosure. As used herein, the singular forms “a” and “an” are intended to include the plural forms as well, unless the context clearly indicates otherwise. It is to be further understood that the terms “includes,” “including,” “comprises,” and/or “comprising,” when used in this specification, specify the presence of stated features, integers, steps, operations, elements, and/or components but do not preclude the presence or addition of one or more other features, integers, steps, operations, elements, components, and/or groups thereof.

Also, any numerical range disclosed and/or recited herein is intended to include all sub-ranges of the same numerical precision subsumed within the recited range. For example, a range of “1.0 to 10.0” is intended to include all sub-ranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

References to two compared elements, features, etc. as being “the same” may mean that they are the same or substantially the same. Thus, the phrase “the same” or “substantially the same” may include a case having a deviation that is considered low in the art, for example, a deviation of 5% or less. In addition, when a certain parameter is referred to as being uniform in a given region, it may mean that it is uniform in terms of an average.

Throughout the specification, unless otherwise stated, each element may be singular or plural.

When an arbitrary element is referred to as being arranged (or located or positioned) on the “above (or below)” or “on (or under)” a component, it may mean that the arbitrary element is placed in contact with the upper (or lower) surface of the component and may also mean that another component may be interposed between the component and any arbitrary element arranged (or located or positioned) on (or under) the component.

In addition, it is to be understood that when an element is referred to as being “coupled,” “linked,” or “connected” to another element, the elements may be directly “coupled,” “linked,” or “connected” to each other, or one or more intervening elements may be present therebetween, through which the element may be “coupled,” “linked,” or “connected” to another element. In addition, when a part is referred to as being “electrically coupled” to another part, the part may be directly electrically connected to another part, or one or more intervening parts may be present therebetween such that the part and the another part are indirectly electrically connected to each other.

Throughout the specification, when “A and/or B” is stated, it means A, B, or A and B, unless otherwise stated. That is, “and/or” includes any or all combinations of a plurality of items enumerated. When “C to D” is stated, it means C or more and D or less, unless otherwise specified.

The terms used in the present specification are for describing embodiments of the present disclosure and are not intended to limit the present disclosure.

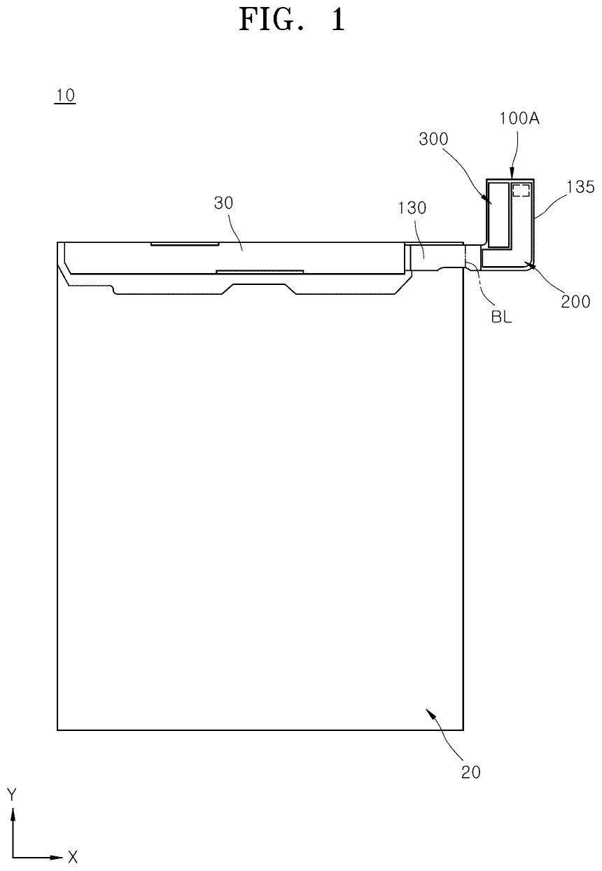

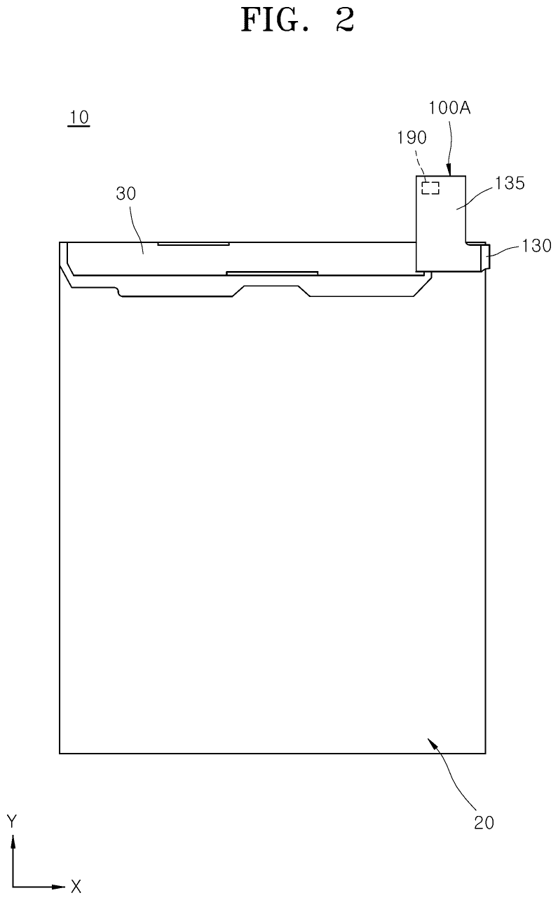

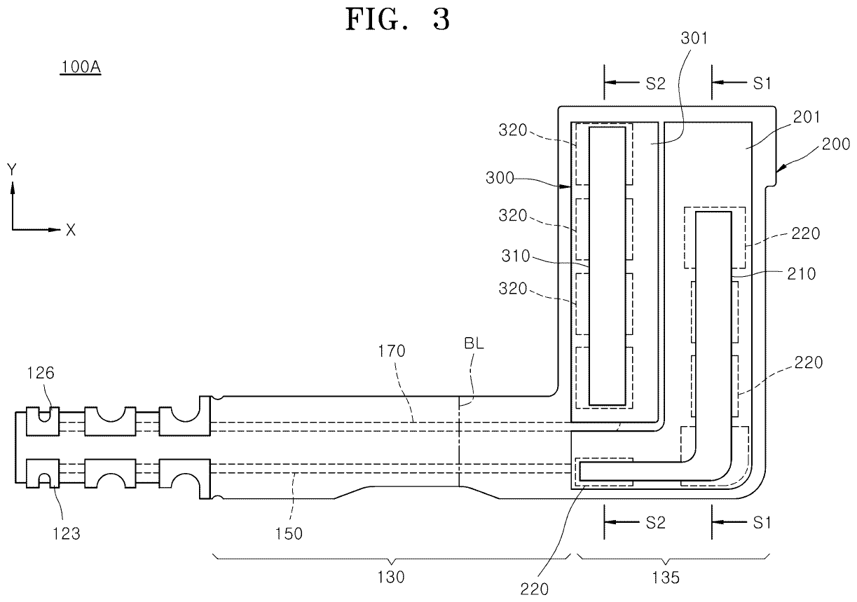

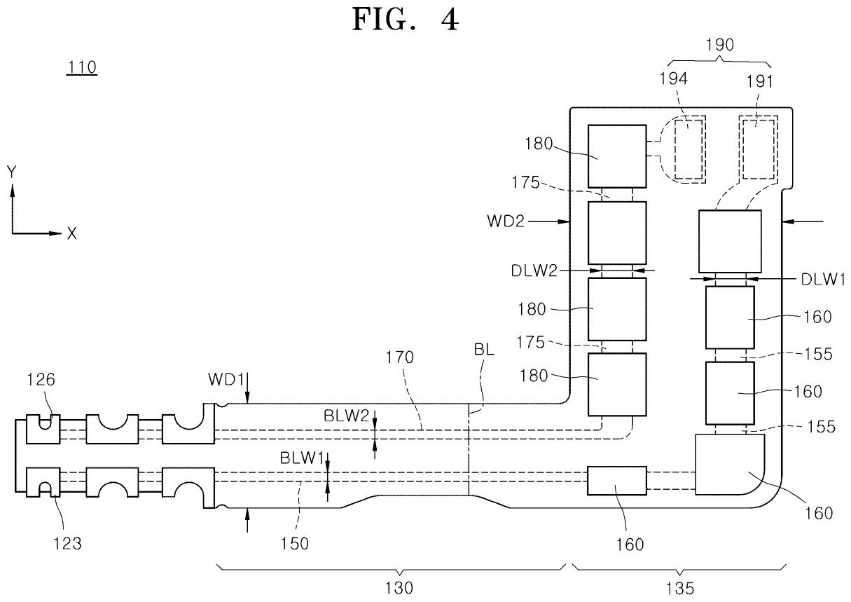

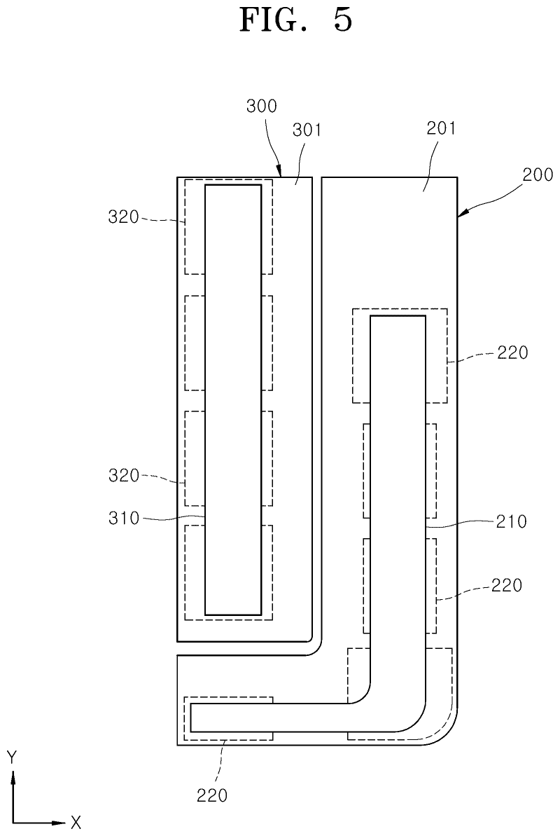

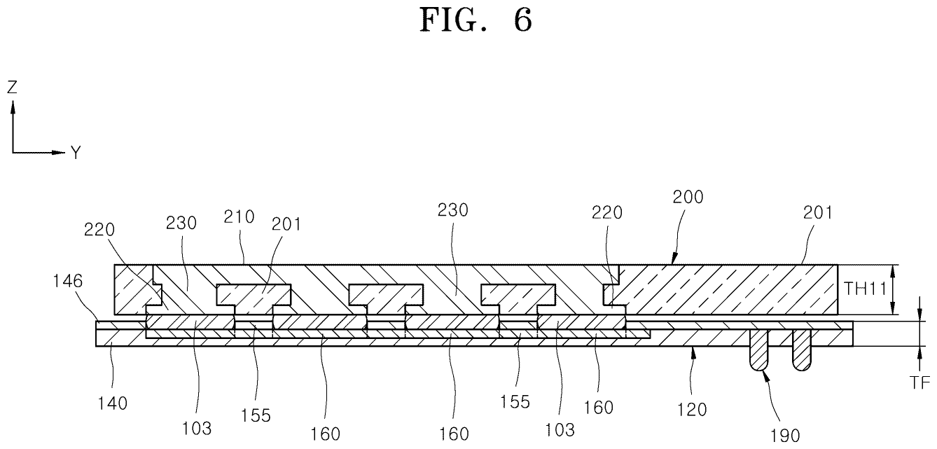

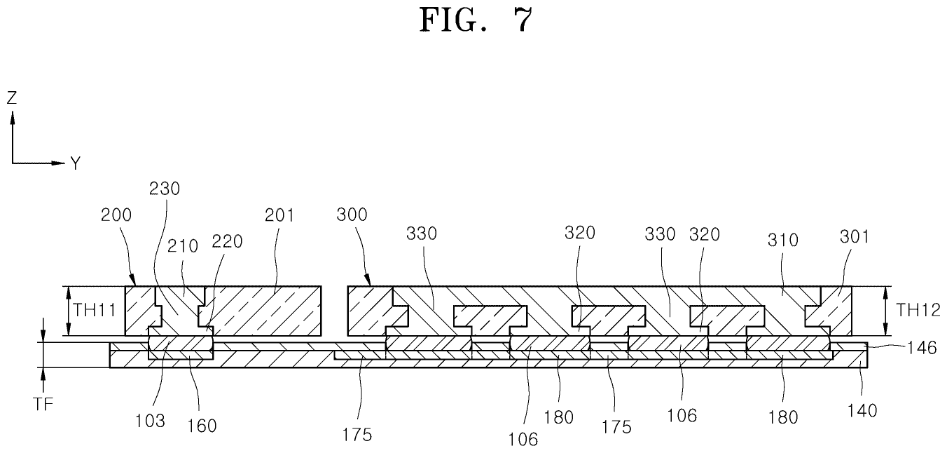

FIG. 1 is a plan view of a battery pack according to an embodiment of the present invention illustrating a state in which a flexible printed circuit board is not folded; FIG. 2 is a plan view of a battery pack according to an embodiment of the present invention illustrating a state in which a flexible printed circuit board is folded; FIG. 3 is a plan view illustrating a hybrid printed circuit board according to an embodiment of the present invention; FIG. 4 is a plan view of a flexible printed circuit board of FIG. 3; FIG. 5 is a plan view of a heat dissipation printed circuit board of FIG. 3; FIG. 6 is a cross-sectional view taken along the line S1-S1 of FIG. 3; and FIG. 7 is a cross-sectional view taken along the line S2-S2 of FIG. 3.

Referring to FIGS. 1 and 2, a battery pack 10 according to an embodiment of the present invention includes a secondary battery 20 and a hybrid printed circuit board 100A. The secondary battery 20 is a unit structure that stores and supplies power and may be, for example, a lithium secondary battery capable of charging and discharging a certain (e.g., a preset) amount of power. The secondary battery 20 according to an embodiment may be, for example, a pouch-type secondary battery including an electrode assembly and an exterior material covering the electrode assembly.

Although not illustrated in the drawings, the electrode assembly may be formed in a winding type in which first and second electrode plates and a separator interposed between the first and second electrode plates are wound in a roll shape, or a stack type in which the first and second electrode plates and separators are stacked.

The battery pack 10 may further include a protection bracket 30 attached to an end of the secondary battery 20. In an embodiment, the protection bracket 30 covers a protection circuit module (PCM) (not shown) to protect the protection circuit module from contamination and/or damage.

The protection circuit module may include, for example, a printed circuit board (PCB). The protection circuit module may block overcharge, overdischarge, and overcurrent of the secondary battery 20 and prevent or substantially prevent a fire due to a short circuit, and may include a circuit pattern formed on the printed circuit board and elements mounted on the printed circuit board.

The battery pack 10 may be installed in a portable electronic device such that a side surface is seated on a bottom surface of a housing of a portable electronic device, such as a laptop computer, a video camera, or a mobile phone.

Referring to FIGS. 1 to 7, the hybrid printed circuit board 100A is electrically connected to the secondary battery 20. For example, the protection circuit module may be directly connected to the first and second terminals of the secondary battery 20, and the hybrid printed circuit board 100A may be directly connected to a pair of flexible printed circuit board connection terminals (not shown) of the protection circuit module.

The hybrid printed circuit board 100A includes a flexible printed circuit board 110 and heat dissipation printed circuit boards 200 and 300. The flexible printed circuit board 110 may include a first flexible film 140, a second flexible film 146, and flexible conductive layers 150, 155, 170, and 175.

The first flexible film 140 and the second flexible film 146 are easily bendable films, and may be, for example, a polyimide film. The polyimide film may be a film having flexibility and insulation.

The flexible conductive layers 150, 155, 170, and 175 may be stacked on the first flexible film 140. The flexible conductive layers 150, 155, 170, and 175 may include, for example, copper (Cu). The second flexible film 146 may be stacked on and bonded to the first flexible film 140 to cover the flexible conductive layers 150, 155, 170, and 175. In an embodiment, the flexible printed circuit board 110 may not include the second flexible film 146 that covers the flexible conductive layers 150, 155, 170, and 175 and is stacked on the first flexible film 140.

A bending part 130 is disposed on a first side of the flexible printed circuit board 110 and a heat dissipation promoting part 135 is disposed on a second side. The bending part 130 and the heat dissipation promoting part 135 may include the first flexible film 140, the second flexible film 146, and the flexible conductive layers 150, 155, 170, and 175.

The flexible conductive layers 150, 155, 170, and 175 may include first flexible conductive layers 150 and 155 and second flexible conductive layers 170 and 175 spaced apart from the first flexible conductive layers 150 and 155. For example, the first flexible conductive layers 150 and 155 may be connected to a positive terminal of a pair of flexible printed circuit board connection terminals (not shown) of the protection circuit module, and the second flexible conductive layers 170 and 175 may be connected to a negative terminal of the pair of flexible printed circuit board connection terminals (not shown) of the protection circuit module.

The first flexible conductive layers 150 and 155 may include a first bending part flexible conductive layer 150 disposed on the bending part 130, and a first heat dissipation promoting part flexible conductive layer 155 disposed on the heat dissipation promoting part 135. The first bending part flexible conductive layer 150 and the first heat dissipation promoting part flexible conductive layer 155 may be connected in a line.

The second flexible conductive layers 170 and 175 may include a second bending part flexible conductive layer 170 disposed on the bending part 130, and a second heat dissipation promoting part flexible conductive layer 175 disposed on the heat dissipation promoting part 135. The second bending part flexible conductive layer 170 and the second heat dissipation promoting part flexible conductive layer 175 may be connected in a line.

The bending part 130 may include first and second board connection terminals 123 and 126 on a side thereof. The first and second board connection terminals 123 and 126 may be joined to the pair of flexible printed circuit board connection terminals of the protection circuit module (not shown). The first board connection terminal 123 may be connected to the first bending part flexible conductive layer 150, and the second board connection terminal 126 may be connected to the second bending part flexible conductive layer 170.

Another side of the bending part 130 may be connected to a side of the heat dissipation promoting part 135. A connector 190 may be installed on another side of the heat dissipation promoting part 135. The connector 190 may be detachably connected to, for example, a connector (not shown) of a portable electronic device. The connector 190 may include a first connection part 191 connected to the first heat dissipation promoting part flexible conductive layer 155, and a second connection part 194 connected to the second heat dissipation promoting part flexible conductive layer 175.

Electrical energy may be discharged from the secondary battery 20 to the portable electronic device through the connector 190 of the heat dissipation promoting part 135 and the connector of the portable electronic device coupled thereto, or portable electrical energy may be introduced to charge the secondary battery 20.

The bending part 130 may include a bending line BL that divides a first side and a second side of the bending part 130 and extends along a straight line. The bending line BL may extend along a straight line crossing both, or opposite, edges of the bending part 130 in a width direction, for example. The first and second board connection terminals 123 and 126 may be disposed on the first side of the bending part 130, and the second side of the bending part 130 may be connected to the heat dissipation promoting part 135 including the connector 190.

The bending part 130 may be folded along the bending line BL such that the first side and the second side of the bending part 130 overlap. The hybrid printed circuit board 100A is shown in FIG. 1 in a state in which the bending part 130 is not folded along the bending line BL, and the hybrid printed circuit board 100A is shown in FIG. 2 in a state in which the bending part 130 is folded along the bending line BL.

The flexible printed circuit board 110 may include heat dissipation printed circuit board connection terminals 160 and 180 connected to the flexible conductive layers 155 and 175 on the heat dissipation promoting part 135. The heat dissipation printed circuit board connection terminals 160 and 180 may include a first heat dissipation printed circuit board connection terminal 160 connected to the first heat dissipation promoting part flexible conductive layer 155, and a second heat dissipation printed circuit board connection terminal 180 connected to the second heat dissipation promoting part flexible conductive layer 175.

The first heat dissipation printed circuit board connection terminal 160 may be formed by partially removing the second flexible film 146 such that the first heat dissipation promoting part flexible conductive layer 155 is exposed at a point (e.g., a predetermined specific point) of the heat dissipation promoting part 135.

In a width direction of the first heat dissipation promoting part flexible conductive layer 155 orthogonal to a longitudinal direction of the first heat dissipation promoting part flexible conductive layer 155, a width of the first heat dissipation printed circuit board connection terminal 160 may be larger than a width of the first heat dissipation promoting part flexible conductive layer 155. A plurality of first heat dissipation printed circuit board connection terminals 160 may be provided to be spaced apart from each other in the longitudinal direction of the first heat dissipation promoting part flexible conductive layer 155.

The second heat dissipation printed circuit board connection terminal 180 may be formed by partially removing the second flexible film 146 such that the second heat dissipation promoting part flexible conductive layer 175 is exposed at a point (e.g., a predetermined specific point) of the heat dissipation promoting part 135.

In the width direction of the second heat dissipation promoting part flexible conductive layer 175 orthogonal to a longitudinal direction of the second heat dissipation promoting part flexible conductive layer 175, a width of the second heat dissipation printed circuit board connection terminal 180 may be larger than a width of second heat dissipation promoting part flexible conductive layer 175. A plurality of second heat dissipation printed circuit board connection terminals 180 may be provided to be spaced apart from each other in the longitudinal direction of the second heat dissipation promoting part flexible conductive layer 175.

The heat dissipation printed circuit boards 200 and 300 overlap the heat dissipation promoting part 135 and are electrically connected to the flexible conductive layers 150, 155, 170, and 175. The heat dissipation printed circuit boards 200 and 300 may include a first heat dissipation printed circuit board 200 and a second heat dissipation printed circuit board 300 spaced apart from each other.

The first heat dissipation printed circuit board 200 may include a first base 201, a first heat dissipation conductive layer 210, a first flexible printed circuit board connection terminal 220, and a first via hole 230. The first heat dissipation conductive layer 210 may be stacked on the first base 201.

The first heat dissipation conductive layer 210 may be formed of, for example, a conductive material, such as copper (Cu). The first heat dissipation conductive layer 210 may extend parallel to the first heat dissipation promoting part flexible conductive layer 155. The first heat dissipation conductive layer 210 may be positioned to overlap the flexible printed circuit board 110 and the heat dissipation printed circuit boards 200 and 300 in the thickness direction.

Referring to FIGS. 1 to 7, for example, a Z-axis direction may be the thickness direction of the flexible printed circuit board 110 and the first heat dissipation printed circuit boards 200 and 300. An X-axis direction may be a longitudinal direction of the bending part 130 and a width direction of the heat dissipation promoting part 135. A Y-axis direction may be a width direction of the bending part 130 and a longitudinal direction of the heat dissipation promoting part 135.

The first flexible printed circuit board connection terminal 220 may be connected to the first heat dissipation conductive layer 210 and may be electrically connected to the first heat dissipation printed circuit board connection terminal 160. The first flexible printed circuit board connection terminal 220 may be formed of, for example, a conductive material, such as copper (Cu).

In an embodiment, a plurality of first flexible printed circuit board connection terminals 220 may be provided to correspond to the plurality of first heat dissipation printed circuit board connection terminals 160 one-to-one. The plurality of first flexible printed circuit board connection terminals 220 may be stacked on the first base 201 in the thickness direction of the flexible printed circuit board 110 and the heat dissipation printed circuit boards 200 and 300 so as to overlap the plurality of first heat dissipation printed circuit board connection terminals 160.

The first flexible printed circuit board connection terminal 220 may be formed on a first side surface of the first base 201 facing the first heat dissipation printed circuit board connection terminal 160. The first heat dissipation conductive layer 210 may be formed on a second side surface of the first base 201 facing away from the first side surface on which the first flexible printed circuit board connection terminal 220 is formed. For example, based on FIGS. 6 and 7, the first flexible printed circuit board connection terminal 220 may be formed on a lower surface of the first base 201, and the first heat dissipation conductive layer 210 may be formed on an upper surface of the first base 201.

The first via hole 230 passes through the first base 201 in the thickness direction to connect the first flexible printed circuit board connection terminal 220 and the first heat dissipation conductive layer 210. For example, the first via hole 230 may be formed by filling a hole passing through the first base 201 in the thickness direction with a conductive material, such as copper (Cu).

The second heat dissipation printed circuit board 300 may include a second base 301, a second heat dissipation conductive layer 310, a second flexible printed circuit board connection terminal 320, and a second via hole 330. The second heat dissipation conductive layer 310 may be stacked on the second base 301.

The second heat dissipation conductive layer 310 may be formed of, for example, a conductive material, such as copper (Cu). The second heat dissipation conductive layer 310 may extend parallel to the second heat dissipation promoting part flexible conductive layer 175. The second heat dissipation conductive layer 310 may be positioned to overlap the flexible printed circuit board 110 and the heat dissipation printed circuit boards 200 and 300 in the thickness direction.

The second flexible printed circuit board connection terminal 320 may be connected to the second heat dissipation conductive layer 310 and may be electrically connected to the second heat dissipation printed circuit board connection terminal 180. The second flexible printed circuit board connection terminal 320 may be formed of, for example, a conductive material, such as copper (Cu).

In an embodiment, a plurality of second flexible printed circuit board connection terminals 320 may be provided to correspond to the plurality of second heat dissipation printed circuit board connection terminals 180 one-to-one. The plurality of second flexible printed circuit board connection terminals 320 may be stacked on the second base 301 in the thickness direction of the flexible printed circuit board 110 and the heat dissipation printed circuit boards 200 and 300 so as to overlap the plurality of second heat dissipation printed circuit board connection terminals 180.

The second flexible printed circuit board connection terminal 320 may be formed on a first side surface of the second base 301 facing the second heat dissipation printed circuit board connection terminal 180. The second heat dissipation conductive layer 310 may be formed on a second side surface of the second base 301 facing away from the first side surface on which the second flexible printed circuit board connection terminal 320 is formed. For example, based on FIGS. 6 and 7, the second flexible printed circuit board connection terminal 320 may be formed on a lower surface of the second base 301, and the second heat dissipation conductive layer 310 may be formed on an upper surface of the second base 301.

The second via hole 330 passes through the second base 301 in the thickness direction to connect the second flexible printed circuit board connection terminal 320 and the second heat dissipation conductive layer 310. For example, the second via hole 330 may be formed by filling a hole passing through the second base 301 in the thickness direction with a conductive material, such as copper (Cu).

In an embodiment, the hybrid printed circuit board 100A may further include a first solder layer 103 and a second solder layer 106. The first solder layer 103 may join the first heat dissipation printed circuit board connection terminal 160 and the first flexible printed circuit board connection terminal 220. The first solder layer 103 may include a solder that is interposed and cured between the first heat dissipation printed circuit board connection terminal 160 and the first flexible printed circuit board connection terminal 220. In an embodiment, a plurality of first solder layers 103 may be provided to correspond to a number of heat dissipation printed circuit board connection terminals 160.

The second solder layer 106 may join the second heat dissipation printed circuit board connection terminal 180 and the second flexible printed circuit board connection terminal 320. The second solder layer 106 may include a solder that is interposed and cured between the second heat dissipation printed circuit board connection terminal 180 and the second flexible printed circuit board connection terminal 320. In an embodiment, a plurality of second solder layers 106 may be provided to correspond to the number of heat dissipation printed circuit board connection terminals 180.

The first heat dissipation printed circuit board 200 may be coupled to the flexible printed circuit board 110 through the first solder layer 103, and the second heat dissipation printed circuit board 300 may be coupled to the flexible printed circuit board 110 through the second solder layer 106. The first heat dissipation printed circuit board 200 may be mounted on the flexible printed circuit board 110 by the first solder layer 103, and the second heat dissipation printed circuit board 300 may be mounted on the flexible printed circuit board 110 by the second solder layer 106.

For example, due to the heat dissipation conductive layers 210 and 310 formed of a conductive material, such as copper (Cu), a magnitude of the total allowable current of the hybrid printed circuit board 100A may be increased, and the heat dissipation performance may be improved.

As a result of conducting a test of charging and discharging a conventional battery pack including a conventional flexible printed circuit board (not shown) and the battery pack 10 of the present invention including the hybrid printed circuit board 100A as shown in FIG. 3, it was confirmed that the temperature of the hybrid printed circuit board 100A was measured to be about 2° C. to 3° C. lower than that of the conventional flexible printed circuit board, and the temperature of the protection circuit module connected to the hybrid printed circuit board 100A was also measured to be lower.

The flexible printed circuit board 110 included in the hybrid printed circuit board 100A may include the bending part 130 that does not overlap the first heat dissipation printed circuit board 200 and the second heat dissipation printed circuit board 300. Therefore, the heat dissipation performance is improved, and the flexible printed circuit board 110 may be bent or folded, and may be applied to various fields.

In the hybrid printed circuit board 100A, a thickness TH11 of the first heat dissipation printed circuit board 200 and a thickness TH12 of the second heat dissipation printed circuit board 300 may be greater than a thickness TF of the flexible printed circuit board 110. In an embodiment, the thickness of the first heat dissipation conductive layer 210 and the thickness of the second heat dissipation conductive layer 310 are increased, and the magnitude of the total allowable current of the hybrid printed circuit board 100A may be further increased, and the heat dissipation performance may be further improved.

In the hybrid printed circuit board 100A, a width WD2 of the heat dissipation promoting part 135 may be larger than a width WD1 of the bending part 130. In an embodiment, the width WD2 of the heat dissipation promoting part 135 is greater than the width WD1 of the bending part 130, a width DLW1 of the flexible conductive layer 155 of the first heat dissipation promoting part may be greater than a width BLW1 of the flexible conductive layer 150 of the first bending part, and a width DLW2 of the flexible conductive layer 175 of the second heat dissipation promoting part may be greater than a width BLW2 of the flexible conductive layer 170 of the second bending part.

Therefore, a magnitude of the allowable current of the flexible printed circuit board 110 is further increased, and heat of the bending part 130 may be easily transferred to the heat dissipation promoting part 135 with the wide width WD2 and dissipated. In an embodiment, the width WD1 of the bending part 130 may be the same as in the case of the existing bending part, such that the hybrid printed circuit board 100A may be bent or folded and installed on the battery pack 10 without difficulty.

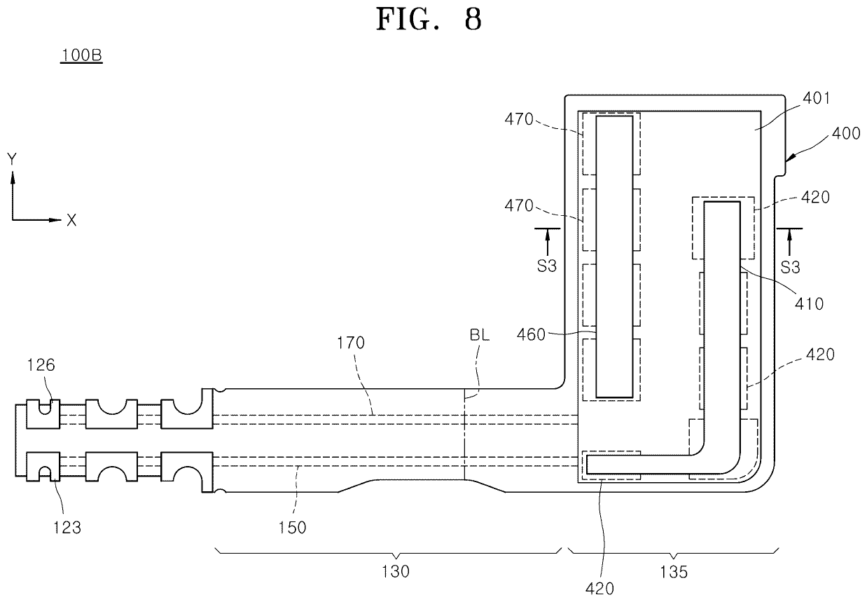

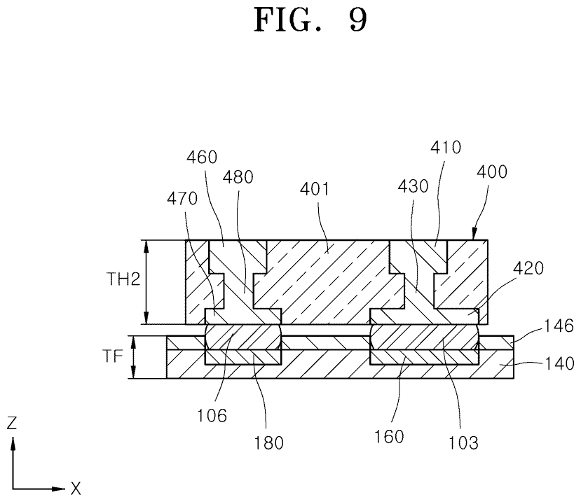

FIG. 8 is an enlarged plan view illustrating a hybrid printed circuit board according to another embodiment of the present invention; and FIG. 9 is a cross-sectional view taken along the line S3-S3 of FIG. 8. A hybrid printed circuit board 100B according to the present embodiment of the present invention shown in FIGS. 8 and 9 may be applied to the battery pack 10 shown in FIGS. 1 and 2 instead of the hybrid printed circuit board 100A according to the previously described embodiment of the present invention.

Referring to FIGS. 8 and 9, a hybrid printed circuit board 100B according to the present embodiment of the present invention includes a flexible printed circuit board 110 and a heat dissipation printed circuit board 400. In an embodiment, the flexible printed circuit board 110 has a same configuration as the flexible printed circuit board 110 included in the hybrid printed circuit board 100A according to the previously described embodiment of the present invention and is indicated by the same reference numerals, and a duplicate description thereof may be omitted.

The heat dissipation printed circuit board 400 overlaps the heat dissipation promoting part 135 and is electrically connected to the flexible conductive layers 150, 155, 170, and 175.

The heat dissipation printed circuit board 400 may include a base 401, a first heat dissipation conductive layer 410, a first flexible printed circuit board connection terminal 420, a first via hole 430, a second heat dissipation conductive layer 460, a second flexible printed circuit board connection terminal 470, and a second via hole 480. The first heat dissipation conductive layer 410 may be stacked on the base 401.

The first heat dissipation conductive layer 410 and the second heat dissipation conductive layer 460 may be formed of, for example, a conductive material, such as copper (Cu). In an embodiment, the first heat dissipation conductive layer 410 and the second heat dissipation conductive layer 460 may be spaced apart from each other and may not intersect.

In an embodiment, the first heat dissipation conductive layer 410 may extend parallel to the first heat dissipation promoting part flexible conductive layer 155 (see FIG. 4). The first heat dissipation conductive layer 410 may be positioned to overlap the flexible printed circuit board 110 and the heat dissipation printed circuit board 400 in the thickness direction.

In an embodiment, the second heat dissipation conductive layer 460 may extend parallel to the second heat dissipation promoting part flexible conductive layer 175 (see FIG. 4). The first heat dissipation conductive layer 410 and the second heat dissipation conductive layer 460 may be positioned to overlap the flexible printed circuit board 110 and the heat dissipation printed circuit board 400 in the thickness direction. Referring to FIGS. 8 and 9, for example, the Z-axis direction may be the thickness direction of the flexible printed circuit board 110 and the heat dissipation printed circuit board 400.

The first flexible printed circuit board connection terminal 420 may be connected to the first heat dissipation conductive layer 410 and may be electrically connected to the first heat dissipation printed circuit board connection terminal 160. The first flexible printed circuit board connection terminal 420 may be formed of, for example, a conductive material, such as copper (Cu).

In an embodiment, a plurality of first flexible printed circuit board connection terminals 420 may be provided to correspond to the plurality of first heat dissipation printed circuit board connection terminals 160 one-to-one. The plurality of first flexible printed circuit board connection terminals 420 may be stacked on the base 401 in the thickness direction of the flexible printed circuit board 110 and the heat dissipation printed circuit board 400 so as to overlap the plurality of first heat dissipation printed circuit board connection terminals 160.

The first flexible printed circuit board connection terminal 420 may be formed on a first side surface of the base 401 facing the first heat dissipation printed circuit board connection terminal 160. The first heat dissipation conductive layer 410 may be formed on a second side surface of the base 401 facing away from the first side surface on which the first flexible printed circuit board connection terminal 420 is formed. For example, based on FIGS. 8 and 9, the first flexible printed circuit board connection terminal 420 may be formed on a lower surface of the base 401, and the first heat dissipation conductive layer 410 may be formed on an upper surface of the base 401.

The second flexible printed circuit board connection terminal 470 may be connected to the second heat dissipation conductive layer 460 and may be electrically connected to the second heat dissipation printed circuit board connection terminal 180. The second flexible printed circuit board connection terminal 470 may be formed of, for example, a conductive material, such as copper (Cu).

In an embodiment, a plurality of second flexible printed circuit board connection terminals 470 may be provided to correspond to the plurality of second heat dissipation printed circuit board connection terminals 180 one-to-one. The plurality of second flexible printed circuit board connection terminals 470 may be stacked on the base 401 in the thickness direction of the flexible printed circuit board 110 and the heat dissipation printed circuit board 400 so as to overlap the plurality of second heat dissipation printed circuit board connection terminals 180.

The second flexible printed circuit board connection terminal 470 may be formed on a first side surface of the base 401 facing the second heat dissipation printed circuit board connection terminal 180. The second heat dissipation conductive layer 460 may be formed on a second side surface of the base 401 facing away from the one side surface on which the second flexible printed circuit board connection terminal 470 is formed. For example, based on FIGS. 8 and 9, the second flexible printed circuit board connection terminal 470 may be formed on a lower surface of the base 401, and the second heat dissipation conductive layer 460 may be formed on an upper surface of the base 401.

The first via hole 430 passes through the base 401 in the thickness direction to connect the first flexible printed circuit board connection terminal 420 and the first heat dissipation conductive layer 410. For example, the first via hole 430 may be formed by filling a hole passing through the base 401 in the thickness direction with a conductive material, such as copper (Cu).

The second via hole 480 passes through the base 401 in the thickness direction to connect the second flexible printed circuit board connection terminal 470 and the second heat dissipation conductive layer 460. For example, the second via hole 480 may be formed by filling a hole passing through the base 401 in the thickness direction with a conductive material, such as copper (Cu).

In an embodiment, the hybrid printed circuit board 100B may further include a first solder layer 103 and a second solder layer 106. The first solder layer 103 may join the first heat dissipation printed circuit board connection terminal 160 and the first flexible printed circuit board connection terminal 420. The first solder layer 103 may include a solder that is interposed and cured between the first heat dissipation printed circuit board connection terminal 160 and the first flexible printed circuit board connection terminal 420. The plurality of first solder layers 103 may be provided to correspond to the number of heat dissipation printed circuit board connection terminals 160.

The second solder layer 106 may join the second heat dissipation printed circuit board connection terminal 180 and the second flexible printed circuit board connection terminal 470. The second solder layer 106 may include a solder that is interposed and cured between the second heat dissipation printed circuit board connection terminal 180 and the second flexible printed circuit board connection terminal 470. In an embodiment, a plurality of second solder layers 106 may be provided to correspond to the number of heat dissipation printed circuit board connection terminals 180.

The heat dissipation printed circuit board 400 may be coupled to the flexible printed circuit board 110 through the first solder layer 103 and the second solder layer 106. The heat dissipation printed circuit board 400 may be mounted on the flexible printed circuit board 110 by the first solder layer 103 and the second solder layer 106.

For example, due to the heat dissipation conductive layers 410 and 460 formed of a conductive material, such as copper (Cu), a magnitude of a total allowable current of the hybrid printed circuit board 100B may be increased and heat dissipation performance may be improved.

In an embodiment, a thickness TH2 of the heat dissipation printed circuit board 400 may be greater than a thickness TF of the flexible printed circuit board 110 in the hybrid printed circuit board 100B. In an embodiment, the thickness of the first heat dissipation conductive layer 410 and the thickness of the second heat dissipation conductive layer 460 are increased, the magnitude of the total allowable current of the hybrid printed circuit board 100B may be further increased, and the heat dissipation performance may be further improved.

A hybrid printed circuit board according to embodiments of the present invention includes a heat dissipation printed circuit board in a portion avoiding a bending portion of a flexible printed circuit board. Accordingly, a magnitude of an allowable current can be increased and heat dissipation performance can be improved without degrading bending performance.

A battery pack according to embodiments of the present invention includes the hybrid printed circuit board of the present invention, which enables rapid charging and discharging, and can prevent or substantially prevent failure or fire accidents due to overheating during charging and discharging.

However, aspects and features of embodiments of the present invention are not limited to those described above, and other aspects and features not mentioned will be clearly understood by those skilled in the art from the detailed description provided above.

Although the present invention has been described with reference to some embodiments and drawings illustrating aspects thereof, the present invention is not limited thereto. Various modifications and variations can be made by a person skilled in the art to which the present invention belongs within the scope of the technical spirit of the invention and the claims and equivalents thereto.

What is claimed is:

1. A hybrid printed circuit board comprising:
a flexible printed circuit board comprising a flexible film that is bendable and a flexible conductive layer stacked on the flexible film, the flexible printed circuit board comprising a bending part located on a first side and a heat dissipation promoting part located on a second side; and
a heat dissipation printed circuit board overlapping the heat dissipation promoting part and electrically connected to the flexible conductive layer.

2. The hybrid printed circuit board as claimed in claim 1, wherein the flexible printed circuit board comprises a heat dissipation printed circuit board connection terminal connected to the flexible conductive layer on the heat dissipation promoting part, and
the heat dissipation printed circuit board comprises a base, a heat dissipation conductive layer stacked on the base, and a flexible printed circuit board connection terminal connected to the heat dissipation conductive layer and electrically connected to the heat dissipation printed circuit board connection terminal.

3. The hybrid printed circuit board as claimed in claim 2, further comprising a solder layer joining the heat dissipation printed circuit board connection terminal and the flexible printed circuit board connection terminal.

4. The hybrid printed circuit board as claimed in claim 2, wherein the flexible printed circuit board connection terminal is on a first side surface of the base facing the heat dissipation printed circuit board connection terminal,
the heat dissipation conductive layer is formed on a second side surface of the base facing away from the first side surface, and
the heat dissipation printed circuit board further comprises a via hole passing through the base in a thickness direction to connect the flexible printed circuit board connection terminal and the heat dissipation conductive layer.

5. The hybrid printed circuit board as claimed in claim 2, wherein the flexible conductive layer comprises a first flexible conductive layer and a second flexible conductive layer spaced apart from the first flexible conductive layer, and
the heat dissipation printed circuit board connection terminal comprises a first heat dissipation printed circuit board connection terminal connected to the first flexible conductive layer, and a second heat dissipation printed circuit board connection terminal connected to the second flexible conductive layer.

6. The hybrid printed circuit board as claimed in claim 5, wherein the heat dissipation printed circuit board comprises a first heat dissipation printed circuit board and a second heat dissipation printed circuit board spaced apart from each other.

7. The hybrid printed circuit board as claimed in claim 6, wherein the first heat dissipation printed circuit board comprises a first base, a first heat dissipation conductive layer stacked on the first base, and a first flexible printed circuit board connection terminal connected to the first heat dissipation conductive layer and electrically connected to the first heat dissipation printed circuit board connection terminal.

8. The hybrid printed circuit board as claimed in claim 6, wherein the second heat dissipation printed circuit board comprises a second base, a second heat dissipation conductive layer stacked on the second base, and a second flexible printed circuit board connection terminal connected to the second heat dissipation conductive layer and electrically connected to the second heat dissipation printed circuit board connection terminal.

9. The hybrid printed circuit board as claimed in claim 5, wherein the heat dissipation conductive layer comprises a first heat dissipation conductive layer and a second heat dissipation conductive layer on the base and spaced apart from each other, and
the flexible printed circuit board connection terminal comprises a first flexible printed circuit board connection terminal on the base and connected to the first heat dissipation conductive layer, and a second flexible printed circuit board connection terminal on the base and connected to the second heat dissipation conductive layer.

10. The hybrid printed circuit board as claimed in claim 1, wherein a thickness of the heat dissipation printed circuit board is greater than a thickness of the flexible printed circuit board.

11. The hybrid printed circuit board as claimed in claim 1, wherein a width of the heat dissipation promoting part is greater than a width of the bending part.

12. The hybrid printed circuit board as claimed in claim 1, wherein the flexible conductive layer comprises a bending part flexible conductive layer on the bending part and a heat dissipation promoting part flexible conductive layer on the heat dissipation promoting part, and
a width of the heat dissipation promoting part flexible conductive layer is greater than a width of the bending part flexible conductive layer.

13. The hybrid printed circuit board as claimed in claim 1, wherein the bending part comprises a bending line that divides a first side and a second side of the bending part and extends along a straight line, and
the bending part is folded along the bending line such that the first side and the second side of the bending part overlap.

14. A battery pack comprising:
a secondary battery; and
a hybrid printed circuit board comprising: a flexible printed circuit board comprising a flexible film that is bendable, and a flexible conductive layer stacked on the flexible film, the flexible printed circuit board comprising a bending part located on a first side and a heat dissipation promoting part located on a second side; and a heat dissipation printed circuit board overlapping the heat dissipation promoting part and electrically connected to the flexible conductive layer.

15. The battery pack as claimed in claim 14, further comprising a battery pack printed circuit board connected to a terminal of the secondary battery,
wherein the flexible printed circuit board further comprises a board connection terminal connected to the battery pack printed circuit board at the bending part, and a connector arranged at the heat dissipation promoting part.

16. The battery pack as claimed in claim 14, wherein the flexible printed circuit board comprises a heat dissipation printed circuit board connection terminal connected to the flexible conductive layer on the heat dissipation promoting part, and
the heat dissipation printed circuit board comprises a base, a heat dissipation conductive layer stacked on the base, and a flexible printed circuit board connection terminal connected to the heat dissipation conductive layer and electrically connected to the heat dissipation printed circuit board connection terminal.

17. The battery pack as claimed in claim 16, wherein the flexible conductive layer comprises a first flexible conductive layer and a second flexible conductive layer spaced apart from the first flexible conductive layer, and
the heat dissipation printed circuit board connection terminal comprises a first heat dissipation printed circuit board connection terminal connected to the first flexible conductive layer, and a second heat dissipation printed circuit board connection terminal connected to the second flexible conductive layer.

18. The battery pack as claimed in claim 16, wherein the heat dissipation printed circuit board comprises a first heat dissipation printed circuit board and a second heat dissipation printed circuit board spaced apart from each other.

19. The battery pack as claimed in claim 18, wherein the first heat dissipation printed circuit board comprises a first base, a first heat dissipation conductive layer stacked on the first base, and a first flexible printed circuit board connection terminal connected to the first heat dissipation conductive layer and electrically connected to the first heat dissipation printed circuit board connection terminal, and
the second heat dissipation printed circuit board comprises a second base, a second heat dissipation conductive layer stacked on the second base, and a second flexible printed circuit board connection terminal connected to the second heat dissipation conductive layer and electrically connected to the second heat dissipation printed circuit board connection terminal.

20. The battery pack as claimed in claim 18, wherein the heat dissipation conductive layer comprises a first heat dissipation conductive layer and a second heat dissipation conductive layer on the base and spaced apart from each other, and
the flexible printed circuit board connection terminal comprises a first flexible printed circuit board connection terminal on the base and connected to the first heat dissipation conductive layer, and a second flexible printed circuit board connection terminal on the base and connected to the second heat dissipation conductive layer.
